(19) United States
(12) Patent Application Publication
(10) Pub. No.: US 2024/0304491 A1
(43) Pub. Date: Sep. 12, 2024

(54) Ceramic Pedestal Shaft with Heated/Cooled Gas Tube

(71) Applicant: Tokyo Electron Limited, Tokyo (JP)

(72) Inventor: Melvin Verbaas, Austin, TX (US)

(21) Appl. No.: 18/179,503

(22) Filed: Mar. 7, 2023

(51) Int. Cl. H01L 21/687; C23C 16/458

(52) U.S. Cl. CPC H01L 21/68757; C23C 16/4586; H01L 21/68785; H01L 21/68792

(57) ABSTRACT

A semiconductor processing apparatus that includes: a wafer pedestal including a ceramic pedestal shaft coupled to an underside of a ceramic wafer chuck, the ceramic pedestal shaft having a central through opening; and ceramic gas delivery tubes embedded within the ceramic pedestal shaft, the ceramic gas delivery tubes being made of a first ceramic material and the ceramic pedestal shaft being made of a second ceramic material, the ceramic gas delivery tubes being coupled to gas channels in the ceramic wafer chuck.

### TECHNICAL FIELD

This invention relates to equipment with pedestals for processing semiconductor substrates and in particular to equipment with ceramic pedestals for processing semiconductor substrates at high temperature.

### BACKGROUND

Semiconductor substrate processing equipment employing wafer pedestals are used to process semiconductor substrates using techniques including etching, physical vapor deposition (PVD), chemical vapor deposition (CVD), plasma-enhanced chemical vapor deposition (PECVD), atomic layer deposition (ALD), plasma-enhanced atomic layer deposition (PEALD), pulsed deposition layer (PDL), plasma-enhanced pulsed deposition layer (PEPDL), and resist removal. The wafer pedestals comprise a wafer chuck upon which the semiconductor substrate rests during processing and a pedestal shaft coupled to the underside of the wafer chuck through which heating or cooling gases and liquids are delivered to the wafer chuck and through which electrical connections are provided to sensors, antennas, and resistance heaters in the wafer chuck. When the processing temperatures exceed 500° C., the wafer chuck is typically made of a ceramic material.

### SUMMARY

In accordance with an embodiment of the present invention, a semiconductor processing apparatus that includes: a wafer pedestal including a ceramic pedestal shaft coupled to an underside of a ceramic wafer chuck, the ceramic pedestal shaft having a central through opening; and ceramic gas delivery tubes embedded within the ceramic pedestal shaft, the ceramic gas delivery tubes being made of a first ceramic material and the ceramic pedestal shaft being made of a second ceramic material, the ceramic gas delivery tubes being coupled to gas channels in the ceramic wafer chuck.

In accordance with an embodiment of the present invention, a method of forming a wafer pedestal assembly that includes: forming a pedestal shaft structure including an central through opening and a ceramic gas delivery tube; sintering the pedestal shaft structure to form a ceramic pedestal shaft with the ceramic gas delivery tube; aligning the ceramic gas delivery tube with a gas channel opening of a ceramic wafer chuck; and attaching the ceramic pedestal shaft to the ceramic wafer chuck with the ceramic gas delivery tube being aligned to the gas channel opening.

In accordance with an embodiment of the present invention, a method of forming a wafer pedestal assembly that includes: forming a pedestal shaft structure including a central through opening and a metal tube within a wall of the pedestal shaft structure; sintering the pedestal shaft structure to form a pedestal shaft with the metal tube; etching the metal tube to form a gas delivery tube disposed within the wall of the pedestal shaft; and attaching the pedestal shaft to a ceramic wafer chuck with the ceramic gas delivery tube being aligned to a gas channel opening of the ceramic wafer chuck.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a block diagram of a semiconductor processing apparatus including a wafer pedestal in accordance with embodiments;

FIG. 2 is a cross sectional view of a wafer pedestal in accordance with embodiments.

FIGS. 3A and 3F are cross sectional views of a wafer pedestal comprising a ceramic wafer chuck and a ceramic pedestal shaft in accordance with embodiments;

FIGS. 3B and 3C are a cross sectional view and a top-down view of a wafer pedestal shaft during various stages of manufacturing in accordance with embodiments;

FIGS. 3D through 3E are a cross sectional view and a top-down view of a wafer pedestal shaft during various stages of manufacturing in accordance with embodiments;

FIG. 4 is a flow diagram with blocks describing wafer pedestal formation in accordance with embodiments;

FIG. 5A and 5F are cross sectional views of a wafer pedestal comprising a ceramic wafer chuck and a ceramic pedestal shaft in accordance with embodiments;

FIGS. 5B through 5C are cross sectional view and a top-down view of a wafer pedestal shaft during various stages of manufacturing in accordance with embodiments;

FIGS. 5D through 5E are cross sectional view and a top-down view of a wafer pedestal shaft during various stages of manufacturing in accordance with embodiments;

FIG. 5H is a top-down view of a wafer pedestal shaft in accordance with embodiments;

FIG. 6 is a flow diagram with blocks describing wafer pedestal formation in accordance with embodiments;

FIG. 7A is a cross sectional view of a wafer pedestal comprising a ceramic wafer chuck and a ceramic pedestal shaft in accordance with embodiments;

FIGS. 7B through 7C are cross sectional views and top-down views of a wafer pedestal shaft during various stages of manufacturing in accordance with embodiments;

FIGS. 7D through 7E are cross sectional views and top-down views of a wafer pedestal shaft during various stages of manufacturing in accordance with embodiments;

FIGS. 7F through 7G are cross sectional views and top-down views of a wafer pedestal shaft during various stages of manufacturing in accordance with embodiments;

FIG. 8 is a flow diagram with blocks describing formation of the wafer pedestal in FIG. 7A in accordance with embodiments;

FIGS. 9A and 9B are cross sectional views of a ceramic gas delivery tube with a resistance heater in accordance with embodiments;

FIG. 10 is a cross sectional view of a ceramic gas delivery tube with a cooling tube coiled around it in accordance with embodiments; and

FIG. 11 is a cross sectional view of a ceramic gas delivery tube with a resistance heater and with a cooling tube coiled around it in accordance with embodiments;

### DETAILED DESCRIPTION OF ILLUSTRATIVE EMBODIMENTS

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

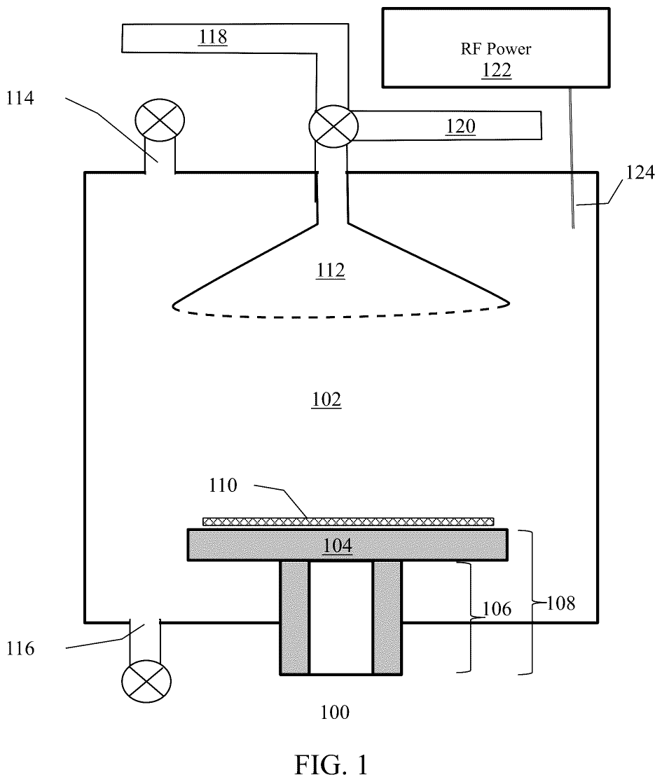

As illustrated in FIG. 1, semiconductor substrates such as a semiconductor wafer 110 are frequently processed on a wafer pedestal 108 in a vacuum chamber 102. The wafer pedestal 108 comprises a wafer chuck 104 upon which the semiconductor wafer 110 rests during processing and a pedestal shaft 106 that supports the wafer chuck 104. The wafer chuck 104 as described in more detail in various embodiments below includes gas delivery tubes embedded within the pedestal shaft 106. The embedded gas delivery tubes may be embedded fully or partially within the walls of the pedestal shaft 106 or attaching to the walls of the pedestal shaft 106 and located within a through opening of the pedestal shaft 106. In certain embodiments, the gas delivery tubes may be made of a first ceramic material and the pedestal shaft 106 may be made of a second ceramic material. The gas delivery tubes may be coupled to gas channels in the ceramic wafer chuck 104.

Process gases are removed from the vacuum chamber 102 through vacuum exhaust port 116. Purge gases can be introduced through gas inlet 114 to return the vacuum chamber 102 to atmospheric pressure. Semiconductor processes including thin film depositions and etches, typically introduce process gases through a showerhead 112 positioned above the semiconductor wafer 110. The showerhead 112 distributes process gases uniformly across the surface of the semiconductor wafer 110. One or more gases can be delivered to showerhead 112 through gas lines 118 and 120. Semiconductor substrate processing machines 100 with plasma processes may also include an RF power supply 122 and antenna 124.

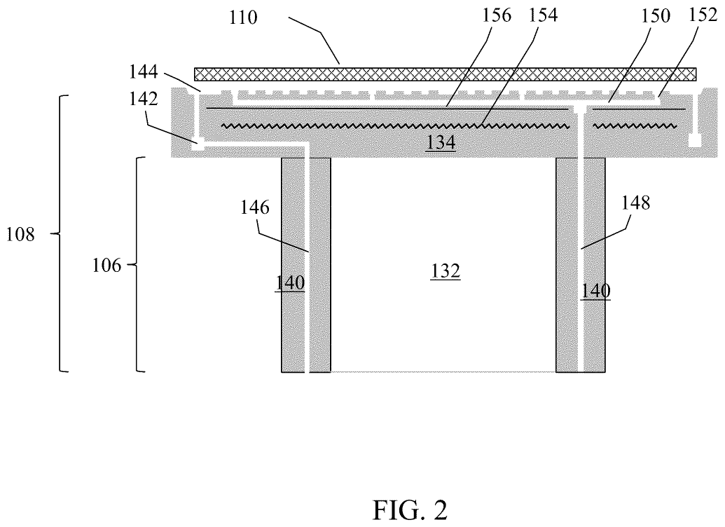

FIG. 2 presents in more detail a cross sectional view of an example semiconductor wafer pedestal 108 used for processing semiconductor substrates such as semiconductor wafers 110 at temperatures exceeding about 500° C. The wafer pedestal 108 comprises ceramic wafer chuck 134 supported by a ceramic pedestal shaft 106. The example ceramic wafer chuck 134 in FIG. 2 includes first and second gas channels 142 and 150 through which gases can flow during processing to heat or cool the semiconductor wafer 110. A resistance heater 154 and an electrostatic chuck antenna 156 may also be incorporated within the ceramic wafer chuck 134.

Wafer heating and cooling gases may be delivered to the backside of the semiconductor wafer 110 through first and second gas channels 142 and 150 in the ceramic wafer chuck 134. Electrical power may be supplied to the resistance heater 154 and the electrostatic chuck antenna 156 in the ceramic wafer chuck 134 through a central through opening 132 in the ceramic pedestal shaft 106. A first ceramic gas delivery tube 146 in the wall 140 of the pedestal shaft 106 supplies heating or cooling gases to first gas channel 142 in the ceramic wafer chuck 134. Gas may be delivered through gas channel 144 in ceramic wafer chuck 134 to the backside of the semiconductor wafer to heat or cool the edge of the semiconductor wafer 110. A second ceramic gas delivery tube 148 also through the wall 140 may supply heating or cooling gases to a second gas channel 150 in the ceramic wafer chuck 134 to heat or cool central portions of the semiconductor wafer 110. The number of ceramic gas delivery tubes and gas channels and their configuration may vary in other wafer chucks and wafer pedestal shafts.

For low temperature processing, wafer pedestals are typically made of a metal such as brass, aluminum, or stainless steel. For processing at temperatures exceeding about 500° C., wafer pedestals are typically made of a ceramic material such as aluminum nitride, aluminum oxide, silicon nitride, silicon carbide, and boron nitride.

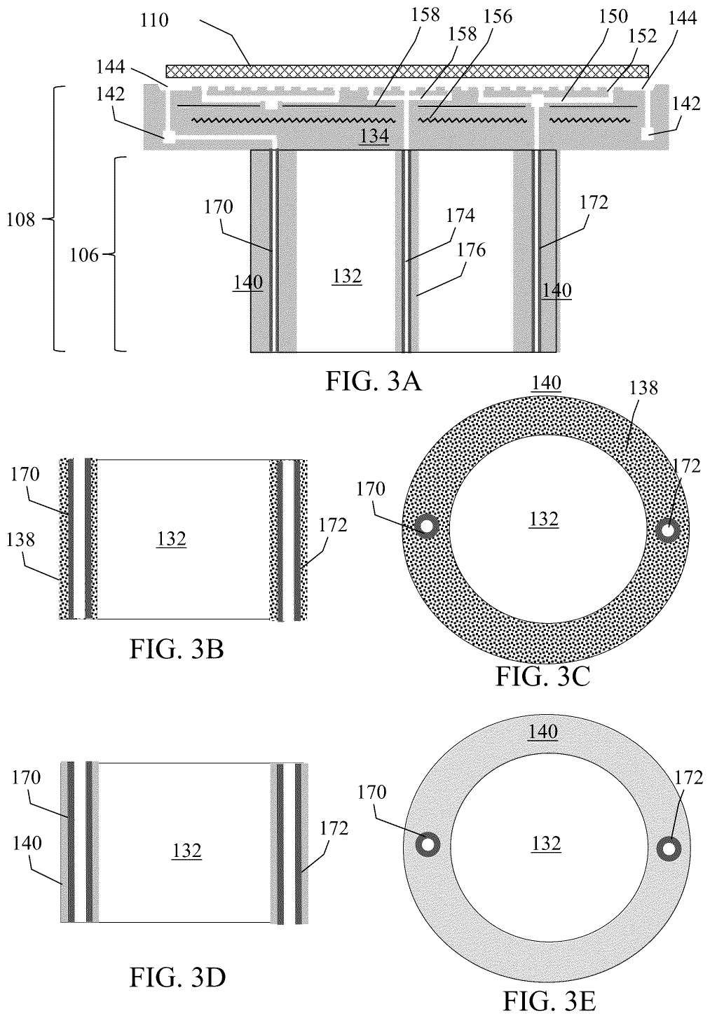

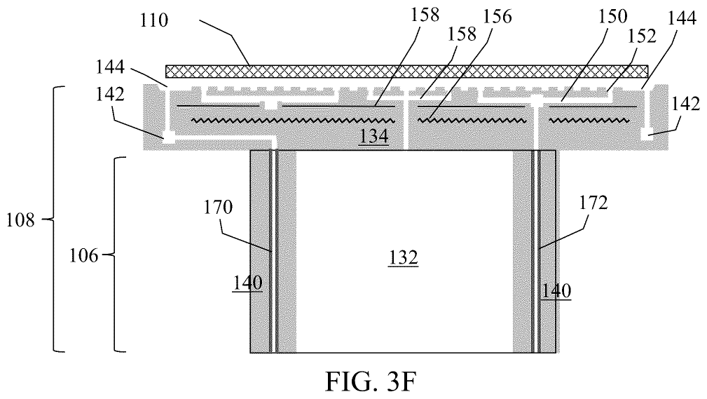

FIG. 3A is a cross sectional view of a wafer pedestal 130 comprised of a ceramic wafer chuck 134 on a ceramic pedestal shaft 106 with ceramic gas delivery tubes 170 and 172 embedded in the walls 140 of the ceramic pedestal shaft 106 and aligned with first and second gas channels 142 and 150 in the ceramic wafer chuck 134. A third ceramic gas delivery tube 174 is coupled to the center of the underside of the ceramic wafer chuck 134 and is aligned with an opening to gas channel 158 in the ceramic wafer chuck 134. Ceramic gas delivery tubes 170, 172, and 174 are formed of ceramic glass that is annealed at a high temperature prior to manufacturing the ceramic pedestal shaft 106. The ceramic gas delivery tubes 170 and 172 are embedded within the walls 140 during manufacture of the ceramic pedestal shaft 106. Gas delivery tube 170 is coupled to gas channel 142 in the ceramic wafer chuck 134 which heats or cools the edge of the wafer 110. Gas delivery tube 172 is coupled to first and second gas channels 150 in the ceramic wafer chuck 134 which heats or cools a donut shaped area between the center and edge of the wafer 110. Ceramic gas delivery tube 174 can be coupled to the center of the ceramic wafer chuck 134 when the ceramic pedestal shaft 106 is coupled to the ceramic wafer chuck 134. Ceramic pedestal shafts 106 are typically coupled to the underside of the ceramic wafer chuck 134 using diffusion bonding.

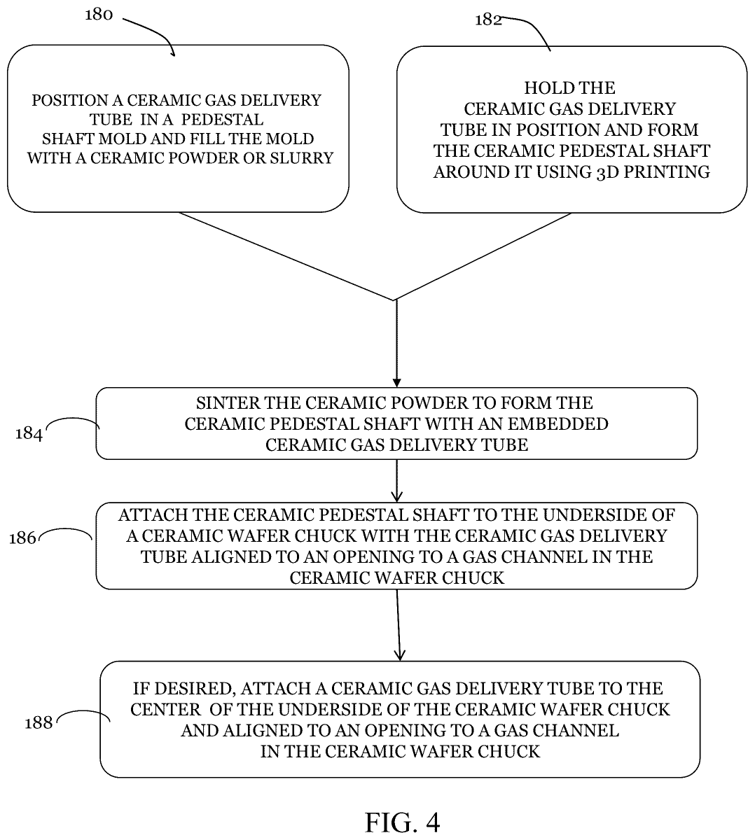

Embodiments describing formation of a wafer pedestal 130 with a ceramic pedestal shaft 106 containing ceramic gas delivery tubes 170 and 172 embedded in a pedestal shaft wall 140 will now be described with reference to FIGS. 3A-3F. FIG. 4 is a flow diagram with blocks describing the major steps for forming the wafer pedestal 130 in FIG. 3A.

Referring to block 180 in FIG. 4 and FIGS. 3B and 3C, ceramic gas delivery tubes 170 and 172 are positioned in a pedestal shaft mold and the mold is filled with a ceramic powder or slurry 138. The mold may be filled using an injection molding or a compression molding process. After the mold is filled with a ceramic power containing slurry or paste, a curing step that may include a bake may be performed to drive off solvent and produce a compacted ceramic powder prior to sintering. The ceramic gas delivery tubes 170 and 172 are formed of a ceramic glass that has been sintered at a high temperature prior to being placed in the mold. They may be formed of a ceramic material selected from a group consisting of aluminum nitride, aluminum oxide, silicon nitride, silicon carbide, and boron nitride.

In certain embodiments, in block 182 of FIG. 4, the ceramic gas delivery tubes 170 and 172 may be held in place and the ceramic pedestal shaft formed around them using 3D printing. The ceramic powder used for 3D printing may comprise a ceramic material selected from a group consisting of aluminum nitride, aluminum oxide, silicon nitride, silicon carbide, and boron nitride.

In block 184 of FIG. 4 and FIGS. 3D and 3E, the ceramic pedestal shaft 106 is sintered at a high temperature to convert the walls 140 of ceramic powder or slurry 138 into a ceramic glass. The ceramic pedestal shaft 106 may be sintered at a temperature above the glass transition temperature of the ceramic powder or slurry 138 and then annealed. The ceramic pedestal shaft 106 may be sintered under pressure to eliminate occluded bubbles and voids. Because of the difference in glass flow properties of the glass ceramic gas delivery tubes 170 and 172 and the ceramic powder or slurry 138 during sintering, an interface forms between the ceramic gas delivery tubes 170 and 172 and the ceramic powder or slurry 138 in the walls 140 of the ceramic pedestal shaft 106. The ceramic material used for the ceramic pedestal shaft 106 may be selected from a group consisting of aluminum nitride, aluminum oxide, silicon nitride, silicon carbide, and boron nitride. The ceramic pedestal shaft 106 may be the same or may be a different ceramic material than the ceramic gas delivery tubes 170, 172, and 174.

In block 186 in FIG. 4 and FIG. 3F, the ceramic pedestal shaft 106 is coupled to the underside of the ceramic wafer chuck 134 with the ceramic gas delivery tubes 170 and 172 aligned with openings to first and second gas channels 142 and 150 in the ceramic wafer chuck 134. The ceramic pedestal shaft 106 may be coupled to the underside of the ceramic wafer chuck 134 using diffusion bonding.

Referring now to block 188 in FIG. 4 and FIG. 3A, if desired, a ceramic gas delivery tube 174 can be aligned to an opening to gas channel 158 in the center of the underside of the ceramic wafer chuck 134 and attached. Gas can flow through this gas channel 158 and exit radially to uniformly heat or cool the center of the wafer 110. If desired, as indicated in FIG. 3A, the sides of ceramic gas delivery tube 174 may be powder coated with ceramic power or slurry 176 and sintered to add reinforcement to the ceramic gas delivery tube.

Embedding ceramic gas delivery tubes 170 and 172 that were previously annealed at high temperature within the walls 140 of the ceramic pedestal shaft 106 prior to sintering ensures stability of the inside diameter of the gas delivery tubes 170 and 172 during the manufacturing process.

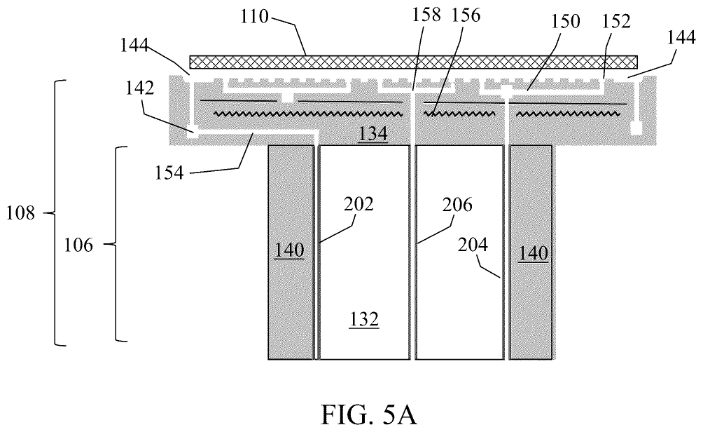

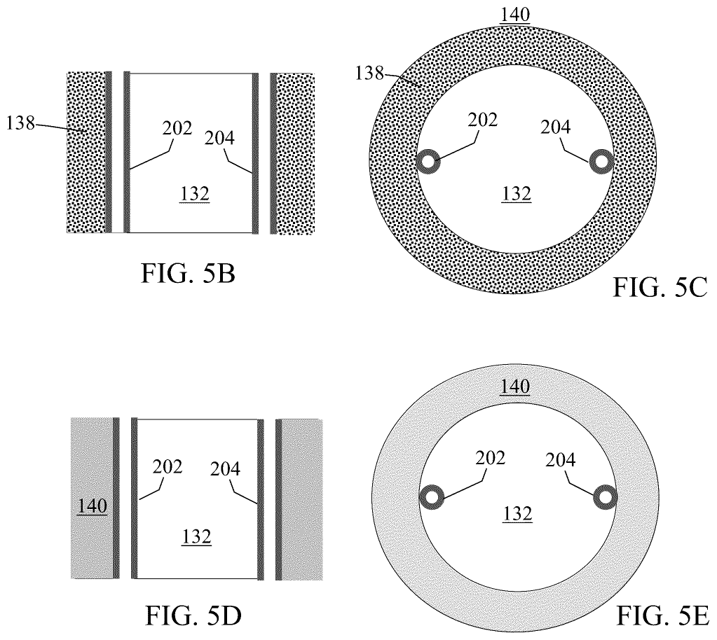

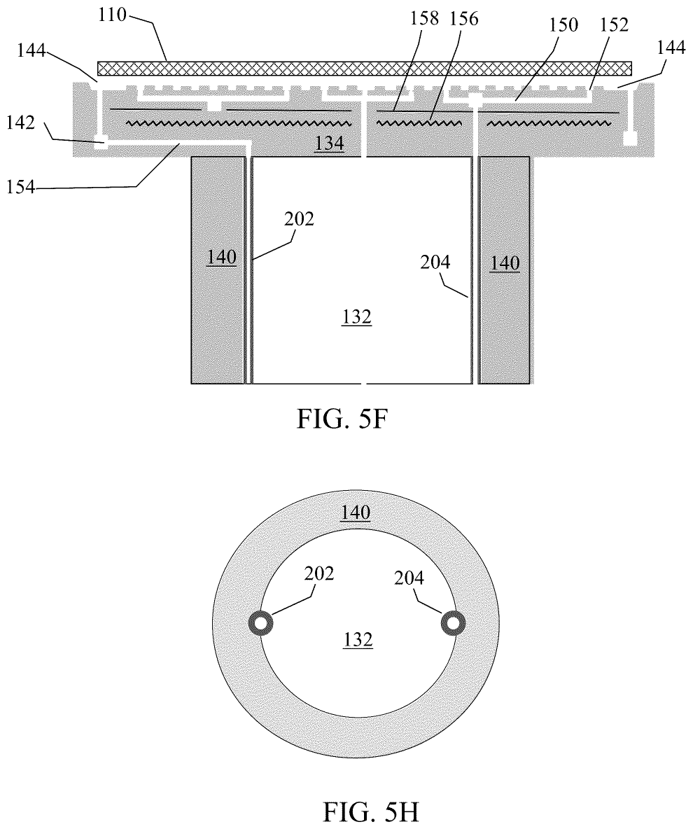

FIG. 5A is a cross sectional view of a wafer pedestal 130 comprised of a ceramic wafer chuck 134 on a ceramic pedestal shaft 106 with ceramic gas delivery tubes 202 and 204 disposed in a central through opening 132 and attached to the inside of the walls 140 of the ceramic pedestal shaft 106. Ceramic gas delivery tube 206 positioned in the middle of the central through opening 132 is coupled to the center of the underside of the ceramic wafer chuck 134. Ceramic gas delivery tubes 202, 204, and 206 are made of a ceramic glass that has been annealed at a high temperature prior to manufacturing the ceramic pedestal shaft 106. Ceramic gas delivery tubes 202 and 204 are disposed within a central through opening 132 and are attached to the inside wall 140 of the ceramic pedestal shaft 106. Gas delivery tube 202 is coupled to gas channel 142 in the ceramic wafer chuck 134 to heat or cool the edge of the wafer 110. Gas delivery tube 204 is coupled to second gas channel 150 in the ceramic wafer chuck 134 to heat or cool a donut shaped area between the center and edge of the wafer 110. Gas delivery tube 206 is coupled to gas channel 158 in the ceramic wafer chuck 134. It delivers heating or cooling gas under the center of the wafer 110 where it spreads out radially providing uniform heating or cooling. Ceramic pedestal shafts 106 are typically coupled to the underside of the ceramic wafer chuck 134 using diffusion bonding.

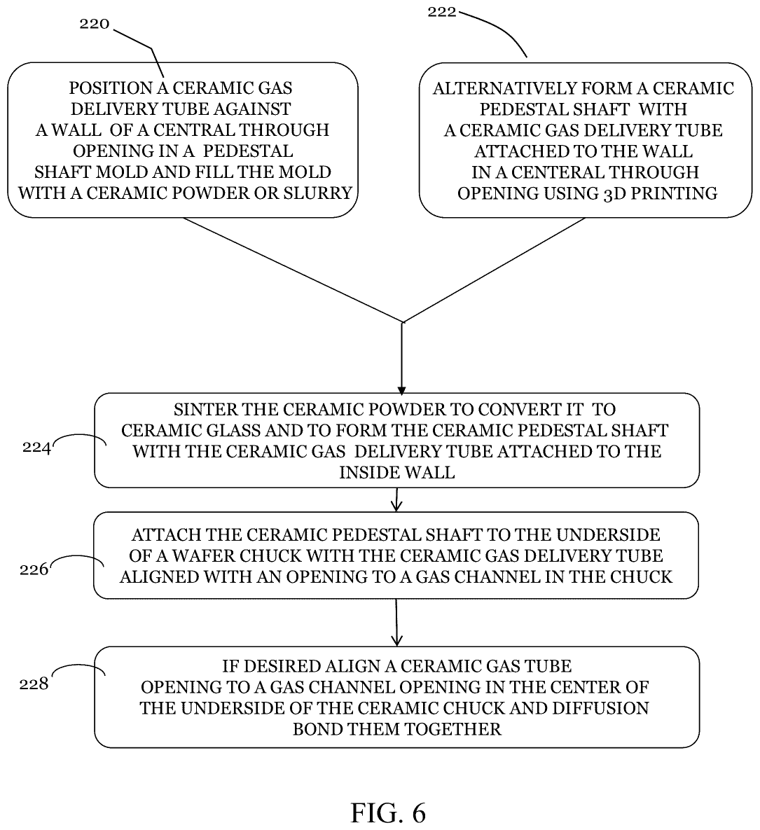

Embodiments describing formation of a wafer pedestal 130 with a ceramic pedestal shaft 106 with ceramic gas delivery tubes 202 and 204 attached to an inside wall 140 in a central through opening 132 will now be described with reference to FIGS. 5A-5F. FIG. 6 is a flow diagram with blocks describing the major steps for forming the wafer pedestal 130 in FIG. 5A. Ceramic gas delivery tubes 202, 204, and 206 typically are made of a ceramic glass that has been annealed at a high temperature. The ceramic material of the ceramic gas delivery tubes 202, 204, and 206 and the ceramic material of the ceramic pedestal shaft 106 may be the same or may be made of different ceramic materials selected from a group consisting of aluminum nitride, aluminum oxide, silicon nitride, silicon carbide, and boron nitride.

Referring to step 220 in FIG. 6 and FIGS. 5B and 5C, a ceramic pedestal shaft 106 is formed using ceramic powder or slurry 138. FIG. 5B is a cross sectional view and FIG. 5C is a top-down view of the ceramic pedestal shaft 106. The ceramic pedestal shaft 106 shown in FIGS. 5B and 5C may be formed by positioning ceramic gas delivery tubes 202 and 204 in a central through opening 132 and against the wall 140 in a pedestal shaft mold. The mold may be filled with ceramic powder or slurry 138 using a process such as injection molding, compression molding, or powder coating.

In certain embodiments, in step 222 of FIG. 6, the ceramic gas delivery tubes 202 and 204 may be held in place and the walls 140 of the ceramic pedestal shaft 106 formed around them using 3D printing. The walls 140 of the ceramic pedestal shaft 106 may be the same ceramic material as the ceramic gas delivery tubes 202 and 204 or may be a different ceramic material.

In block 224 of FIG. 6 and FIGS. 5D and 5E, the ceramic pedestal shaft is sintered at a temperature sufficiently high to convert the walls 140 made of ceramic powder or slurry 138 to ceramic glass. The ceramic pedestal shaft 106 may be sintered while under pressure to eliminate occluded bubbles and voids. The ceramic material may be selected from a group consisting of aluminum nitride, aluminum oxide, silicon nitride, silicon carbide, and boron nitride. The ceramic material of the ceramic pedestal shaft 106 may be the same or may be different than the ceramic material of the ceramic gas delivery tubes 202 and 204.

In blocks 226 in FIG. 6 and FIG. 5F, the ceramic pedestal shaft 106 is coupled to the underside of the ceramic wafer chuck 134 with ceramic gas delivery tubes 202 and 204 aligned with openings to first and second gas channels 142 and 150 in the underside of the ceramic wafer chuck 134. The ceramic pedestal shaft 106 may be coupled to the underside of the ceramic wafer chuck 134 using diffusion bonding.

Referring now to block 228 in FIG. 6 and FIG. 5A, in certain embodiments, a ceramic gas delivery tube 206 may be aligned with an opening to gas channel 158 in the center of the underside of the ceramic wafer chuck 134 and coupled to the ceramic wafer chuck 134. Gas exiting from gas channel 158 under the center of the wafer 110 may flow in a radial direction outward providing uniform heating or cooling.

Using gas delivery tubes 202, 204, and 206 that have previously been annealed at a high temperature when sintering the pedestal shaft ensures stability of the inside diameter of the gas delivery tubes 202, 204, and 206.

FIG. 5H is a top-down view of a wafer pedestal shaft in accordance with embodiments.

As illustrated in FIG. 5H, in certain embodiments, the gas delivery tubes 202, 204 maybe partially embedded within the sidewalls of the central through opening 132. The sidewalls of the central through opening 132 maybe designed to include notches for partially embedding the gas delivery tubes 202, 204 for better mechanical support. The embedding of the gas delivery tubes 202, 204 may be performed during the molding process described in step 220 or the 3D printing described in step 222.

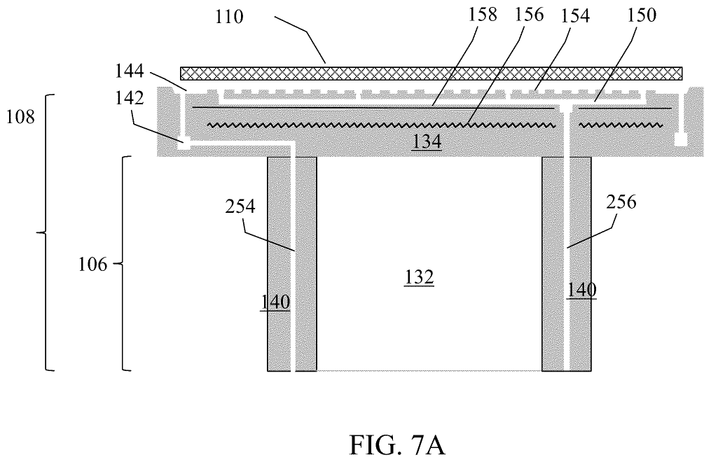

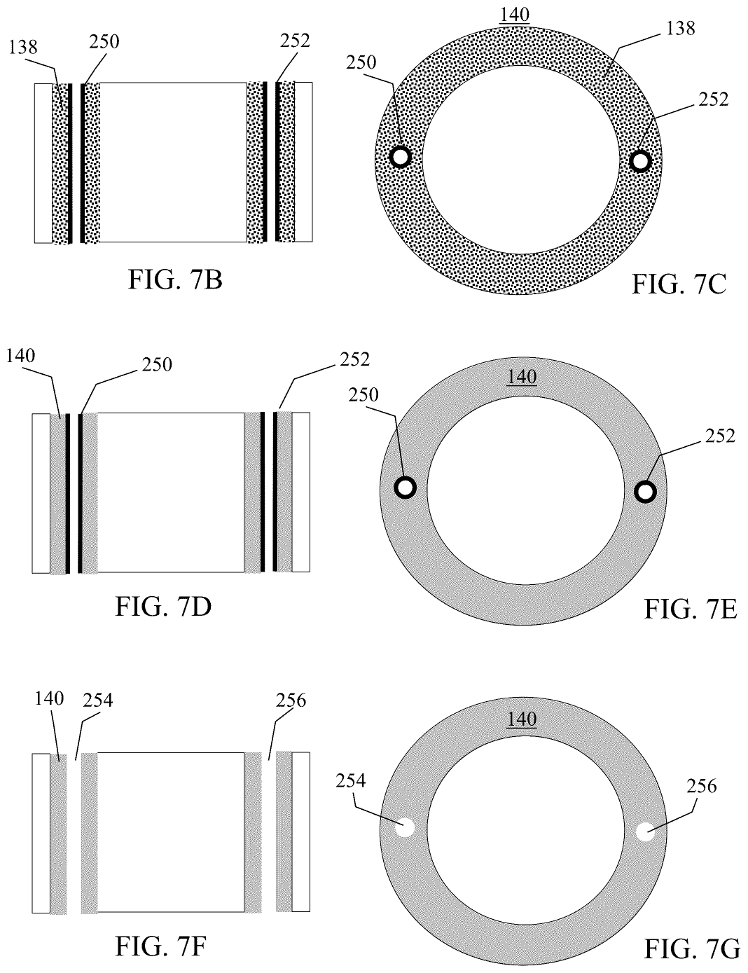

FIG. 7A is a cross sectional view of a wafer pedestal 130 comprised of a ceramic pedestal shaft 106 with ceramic gas delivery tubes 254 and 256 running through the vertical length of the ceramic pedestal shaft 106 and coupled to the underside of a ceramic wafer chuck 134. Gas delivery tube 254 is coupled to gas channel 142 in the ceramic wafer chuck 134 to heat or cool the edge of the wafer 110. Gas delivery tube 256 is coupled to second gas channel 150 in the ceramic wafer chuck 134 to heat or cool the center area of the wafer 110. The ceramic pedestal shaft 106 is typically coupled to the underside of the ceramic wafer chuck 134 using diffusion bonding.

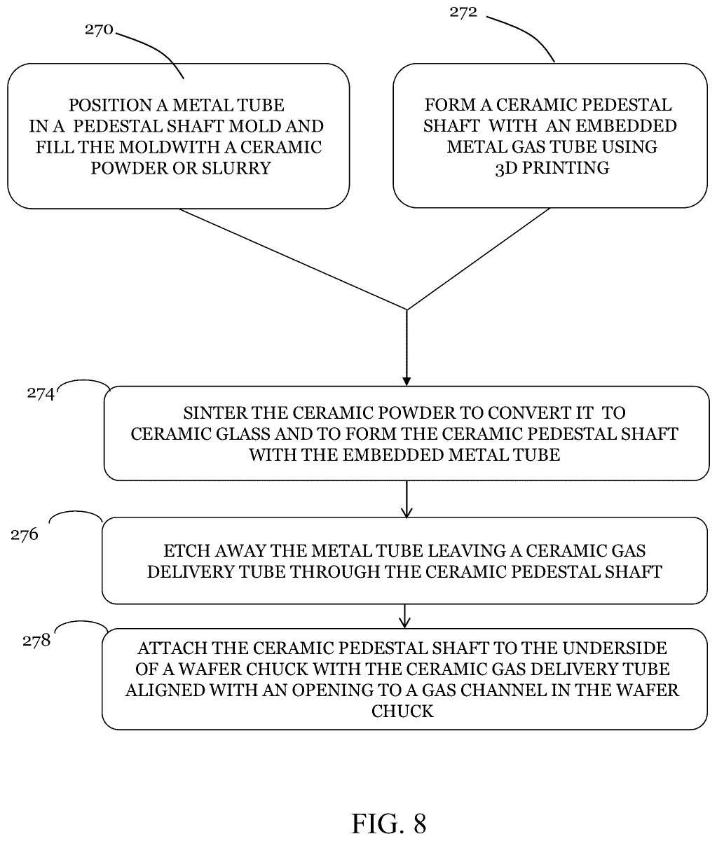

Embodiments describing formation of a wafer pedestal 130 with a ceramic pedestal shaft 106 containing ceramic gas delivery tubes 254 and 256 embedded in the pedestal shaft wall 140 will now be described with reference to FIGS. 7A-7G. FIG. 8 is a flow diagram with blocks describing the major steps for forming the wafer pedestal 130 in FIG. 7A

In block 270 of FIG. 8 and FIGS. 7B and 7C, a ceramic pedestal shaft 106 with metal tubes 250 and 252 embedded in the wall 140 is formed using ceramic powder or slurry 138. Unlike the prior embodiments, this embodiment uses tubes made of metal to provide stability to the inside diameter of the first and second gas delivery tubes 254 and 256 during manufacture of the ceramic pedestal shaft 106. FIG. 7B is a cross sectional view and FIG. 7C is a top-down view of the ceramic pedestal shaft 106. The metal tubes 250 and 252 may be positioned in a pedestal shaft mold that can then be filled with ceramic powder or ceramic slurry 138 using for example a process such as injection molding, compression molding, or powder coating.

In certain embodiments, in block 272 of FIG. 8, the metal tubes 250 and 252 may be held in place and the ceramic pedestal shaft 106 formed around them using 3D printing.

In various embodiments, the ceramic material for the molding process or the 3D printing may be selected from a group consisting of aluminum nitride, aluminum oxide, silicon nitride, silicon carbide, and boron nitride.

In block 274 of FIG. 8 and FIGS. 7D and 7E, the ceramic powder or slurry 138 is sintered at a high temperature to form a ceramic pedestal shaft 106 with a wall 140 made of ceramic glass. The ceramic pedestal shaft 106 may be sintered at a temperature above the glass transition temperature of the ceramic powder or slurry 138 and then annealed. The ceramic pedestal shaft 106 may be sintered while under pressure to eliminate occluded bubbles and voids.

Referring now to block 276 in FIG. 8 and FIGS. 7F and 7G, an acid such as hydrochloric acid, nitric acid, or sulfuric acid may be used to etch away the metal tubes 250 and 252. This leaves first and second ceramic gas delivery tubes 254 and 256 through the wall 140 of the ceramic pedestal shaft 106.

In block 278 of FIG. 8 and FIG. 7A the ceramic pedestal shaft 106 may be coupled to the underside of the ceramic wafer chuck 134 with first ceramic gas delivery tube 254 aligned to first gas channel 142 in the ceramic wafer chuck 134 and with second ceramic gas delivery tube 256 aligned to second gas channel 150 in the ceramic wafer chuck 134.

Embedding metal tubes, 250 and 252 in the walls 140 of the ceramic pedestal shaft 106 prior to sintering the ceramic pedestal shaft 106 ensures stability of the inside diameter of the ceramic gas delivery tubes 254 and 256 during manufacturing. Removing the metal tubes, 250 and 252, after sintering prevents metal contamination that might otherwise occur due to chemical reactions between the metal tubes 250 and 252 and process gases.

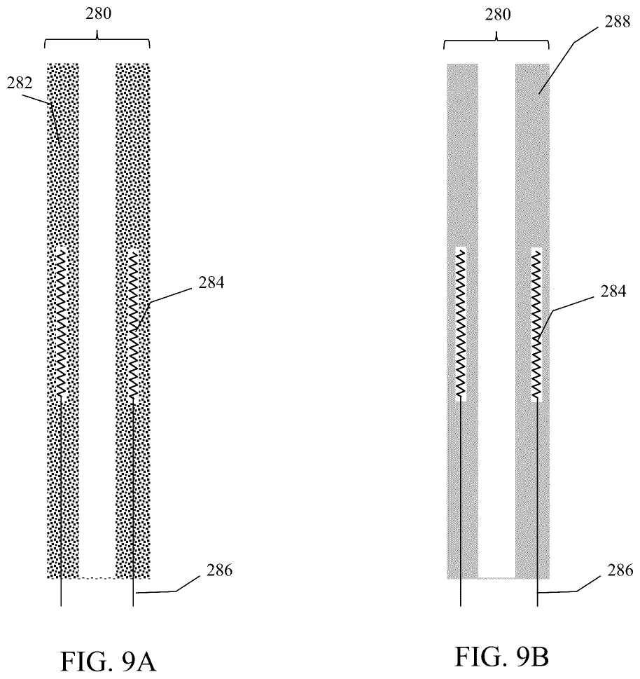

Embodiments describing gas delivery tubes 280 modified to heat or cool the gases being delivered to the wafer chuck are illustrated in FIGS. 9A, 9B, 10, and 11.

FIGS. 9A and 9B illustrate a method of manufacturing a gas delivery tube 280 with an embedded resistance heater 284. In FIG. 9A, a resistance heater 284 with a wire 286 attached to provide electrical power to the resistance heater 284 may be positioned in a gas delivery tube mold which is then filled with ceramic powder 282. FIG. 9B shows the gas delivery tube 280 after it has been sintered at high temperature to convert the ceramic powder 282 to ceramic glass 288. The resistance heater 284 may be turned on to heat the gas being delivered to the gas channels in the wafer chuck.

FIG. 10 is a side view of a gas delivery tube 280 with a cooling tube 290 coiled around it. Cold gases or liquids may be circulated through the cooling tube 290 to cool the gas being delivered to the gas channels in the wafer chuck.

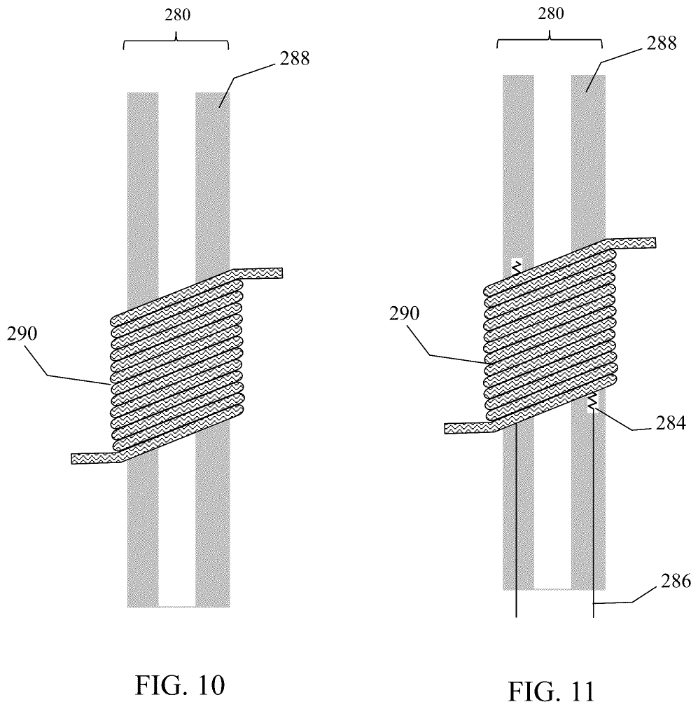

FIG. 11 is a side view of a gas delivery tube 280 with both a resistance heater 284 embedded in the wall of the gas delivery tube 280 and with a cooling tube 290 coiled around the gas delivery tube 280. This configuration may be used to sequentially heat and cool gases being delivered to the gas channels in the wafer chuck during wafer processing. For example, a wafer may be cooled during a plasma etching process that generates the heat to keep a photo resist from degrading and then may be heated to help ash the photoresist once the etching is completed.

As discussed above, an embodiment ceramic pedestal shaft with a ceramic gas delivery tube running through a wall of the ceramic pedestal shaft is coupled to the underside of a ceramic wafer chuck with the gas delivery tube aligned to a gas channel opening in the ceramic wafer chuck. In embodiments, an interface is formed between the ceramic gas delivery tube material and the ceramic pedestal shaft material. In other embodiments, the ceramic tube is disposed in a through hole opening in the ceramic pedestal shaft and is attached to the inside wall of the ceramic pedestal shaft. In embodiments a ceramic tube is aligned to a gas channel opening and is coupled to the center of the underside of a ceramic wafer chuck.

In embodiments, the ceramic gas delivery tube and the ceramic pedestal shaft are formed of different ceramic materials. In other embodiments, the ceramic gas delivery tube and the ceramic pedestal shaft are formed of the same ceramic material.

In embodiments, a ceramic gas delivery tube is positioned in a pedestal shaft mold, the mold is filled with ceramic powder, and the ceramic powder is sintered to convert it to a ceramic pedestal shaft made of ceramic glass. In one embodiment the ceramic gas delivery tube is embedded in a wall of the ceramic pedestal shaft. In another embodiment the ceramic gas delivery tube disposed in a central through opening and attached to the inside wall of ceramic pedestal shaft.

In embodiments, a ceramic gas delivery tube is held in place and the ceramic pedestal shaft is 3D printed around it. In one embodiment the ceramic pedestal shaft is 3D printed with the ceramic gas delivery tube embedded in the ceramic pedestal shaft. In another embodiment the ceramic pedestal shaft is 3D printed with the ceramic gas delivery tube attached to the inside wall of a central through opening in the ceramic pedestal shaft.

In embodiments, a metal tube is positioned in a pedestal shaft mold, the mold is filled with ceramic powder, the ceramic powder is sintered converting it to a ceramic pedestal shaft made of ceramic glass, and the metal tube is etched away forming a ceramic gas delivery tube through the ceramic pedestal shaft. Example embodiments of the present invention are summarized here. Other example embodiments can also be understood from the entirety of the specification and the claims filed herein.

Example 1. A semiconductor substrate processing apparatus includes a wafer pedestal, the wafer pedestal comprising a ceramic pedestal shaft coupled to the underside of a ceramic wafer chuck, the ceramic pedestal shaft having a ceramic gas delivery tube in the ceramic pedestal shaft aligned with an opening to a gas channel in the ceramic wafer chuck.

Example 2. The semiconductor substrate processing apparatus of Example 1 further including embedding the ceramic gas delivery tube in a wall of the ceramic pedestal shaft.

Example 3. The semiconductor substrate processing apparatus of Example 1 further including attaching the ceramic gas delivery tube to the inside wall of a central through opening in the ceramic pedestal shaft.

Example 4: The semiconductor substrate processing apparatus of one of Examples 1, 2, and 3 with the ceramic gas delivery tube made of a first ceramic material and the ceramic pedestal shaft made of a second ceramic material.

Example 5: The semiconductor substrate processing apparatus of one of Examples 1, 2, and 3 with the ceramic gas delivery tube and the ceramic pedestal shaft made of the same ceramic material.

Example 6: The semiconductor substrate processing apparatus of one of Examples 1, 2, and 3 with a second ceramic gas delivery tube coupled to the center of the underside of the ceramic wafer chuck and aligned to an opening to a gas channel in the ceramic wafer chuck.

Example 7: The semiconductor substrate processing apparatus of one of Examples 1, 2, 3, 4, 5, and 6 with a heater embedded in the wall of the ceramic gas delivery tube.

Example 8: The semiconductor substrate processing apparatus of one of Examples 1, 2, 3, 4, 5, and 6 with a cooling tube coiled around the ceramic gas delivery tube.

Example 9: The semiconductor substrate processing apparatus of one of Examples 1, 2, 3, 4, 5, and 6 with a cooling tube coiled around the ceramic gas delivery tube and a heater embedded in the wall of the ceramic gas delivery tube

Example 10: The semiconductor substrate processing apparatus of one of Examples 8 and 9 wherein the cooling tube comprises a metal selected from a group consisting of nickel, tungsten, molybdenum, titanium, or tungsten carbide.

Example 11: A method of forming a semiconductor substrate processing apparatus by positioning a ceramic gas delivery tube in a pedestal shaft mold, filling the mold with a ceramic powder or slurry, sintering the ceramic powder or slurry to convert the ceramic powder or slurry into a ceramic pedestal shaft made of ceramic glass, and attaching the ceramic pedestal shaft to the underside of a ceramic wafer chuck with the ceramic gas delivery tube aligned with an opening to a gas channel in the ceramic wafer chuck.

Example 12: A method of forming a semiconductor substrate processing apparatus by 3D printing a ceramic pedestal shaft around a ceramic gas delivery tube.

Example 13: The method of Example 12 further comprising forming a central through opening in the ceramic pedestal shaft.

Example 14: The method of one of Examples 11 and 12 including forming the ceramic pedestal shaft with the ceramic gas delivery tube embedded in the wall.

Example 15: The method of one of Examples 11, 12, and 13 including forming the ceramic pedestal shaft with the ceramic gas delivery tube attached to the inside wall in a central through opening.

Example 16: The method of Example 11 including filling the pedestal shaft mold using process such as injection molding, compression molding, or powder coating.

Example 17: The method of one of Examples 11, 12, 13, 14 and 15 including making the ceramic gas delivery tube of a first ceramic material and the ceramic pedestal shaft of a second ceramic material.

Example 18: The method of one of Examples 11, 12, 13, 14, and 15 including making the ceramic gas delivery tube and the ceramic pedestal shaft of the same ceramic material.

Example 19: The method of one of Examples 11, 12, 13, 14, 15, 17 and 18 including selecting the ceramic material from a group consisting of aluminum nitride, aluminum oxide, silicon nitride, silicon carbide, and boron nitride.

Example 20: A method of forming a semiconductor substrate processing apparatus by positioning a metal tube in a pedestal shaft mold, filling the mold with a ceramic powder or slurry, sintering the ceramic powder or slurry to turn the ceramic powder or slurry into ceramic pedestal shaft made of ceramic glass, removing the metal tube by etching and forming a ceramic gas delivery tube in the ceramic pedestal shaft, and attaching the ceramic pedestal shaft to the underside of a ceramic wafer chuck with the ceramic gas delivery tube aligned with an opening to a gas channel in the ceramic wafer chuck.

Example 21: The method of one of Examples 11 and 20 using diffusion bonding to couple the ceramic pedestal shaft to the ceramic wafer chuck.

Example 22: The method of one of Examples 11 and 20 further including coupling a ceramic gas delivery tube to the middle of the underside of the ceramic wafer chuck and aligned with an opening to a gas channel in the ceramic wafer chuck.

Example 23: The method of Example 20 including selecting the ceramic material from a group consisting of aluminum nitride, aluminum oxide, silicon nitride, silicon carbide, and boron nitride. In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

Example embodiments of the invention are summarized here. Other embodiments can also be understood from the entirety of the specification as well as the claims filed herein.

Example 1. A semiconductor processing apparatus that includes: a wafer pedestal including a ceramic pedestal shaft coupled to an underside of a ceramic wafer chuck, the ceramic pedestal shaft having a central through opening; and ceramic gas delivery tubes embedded within the ceramic pedestal shaft, the ceramic gas delivery tubes being made of a first ceramic material and the ceramic pedestal shaft being made of a second ceramic material, the ceramic gas delivery tubes being coupled to gas channels in the ceramic wafer chuck.

Example 2. The apparatus of example 1, where the first ceramic material and the second ceramic material are separated from each other by an interface region.

Example 3. The apparatus of one of examples 1 or 2, where the first ceramic material and the second ceramic material have different chemical composition.

Example 4. The apparatus of one of examples 1 to 3, further including: a first of the ceramic gas delivery tubes centered within the through opening and coupled to a first gas channel opening in a center of the underside of the ceramic wafer chuck; and a second of the ceramic gas delivery tubes embedded in a wall of the ceramic pedestal shaft and coupled to a second gas channel opening in a peripheral region of the underside of the ceramic wafer chuck.

Example 5. The apparatus of one of examples 1 to 4, further including: a first of the ceramic gas delivery tubes centered within the through opening and coupled to a gas channel opening in a center of the underside of the ceramic wafer chuck; and a second of the ceramic gas delivery tubes disposed within the central through opening and attached to an inside wall of the ceramic pedestal shaft.

Example 6. The apparatus of one of examples 1 to 5, further including a resistance heater embedded in one of the ceramic gas delivery tubes.

Example 7. The apparatus of one of examples 1 to 6, further including a cooling tube coiled around one of the ceramic gas delivery tubes.

Example 8. The apparatus of one of examples 1 to 7, where the cooling tube includes a metal selected from a group consisting of nickel, tungsten, molybdenum, titanium, and tungsten carbide.

Example 9. The apparatus of one of examples 1 to 8, further including a resistance heater embedded in one of the ceramic gas delivery tubes and with a cooling tube coiled around one of the ceramic gas delivery tubes with an embedded resistance heater.

Example 10. The apparatus of one of examples 1 to 9, where the ceramic pedestal shaft is made of a ceramic material selected from a group consisting of aluminum nitride, aluminum oxide, silicon nitride, silicon carbide, and boron nitride.

Example 11. The apparatus of one of examples 1 to 10, where the first ceramic material is selected from a group consisting of aluminum nitride, aluminum oxide, silicon nitride, silicon carbide, and boron nitride.

Example 12. The apparatus of one of examples 1 to 11, where the first ceramic material and the second ceramic material are made of aluminum nitride.

Example 13. The apparatus of one of examples 1 to 12, where the ceramic pedestal shaft is diffusion bonded to the underside of the ceramic wafer chuck.

Example 14. A method of forming a wafer pedestal assembly that includes: forming a pedestal shaft structure including an central through opening and a ceramic gas delivery tube; sintering the pedestal shaft structure to form a ceramic pedestal shaft with the ceramic gas delivery tube; aligning the ceramic gas delivery tube with a gas channel opening of a ceramic wafer chuck; and attaching the ceramic pedestal shaft to the ceramic wafer chuck with the ceramic gas delivery tube being aligned to the gas channel opening.

Example 15. The method of example 14, where forming the pedestal shaft structure includes placing the ceramic gas delivery tube in a mold, performing a powder coating process to coat the ceramic gas delivery tube with a ceramic powder, and removing the pedestal shaft structure from the mold after a curing process.

Example 16. The method of one of examples 14 or 15, where forming the pedestal shaft structure includes performing a compression molding process.

Example 17. The method of one of examples 14 to 16, where forming the pedestal shaft structure includes performing an injection molding process.

Example 18. The method of one of examples 14 to 17, where forming the pedestal shaft structure includes performing a 3-D printing process.

Example 19. The method of one of examples 14 to 18, where the ceramic gas delivery tube is placed within a wall of the pedestal shaft structure.

Example 20. The method of one of examples 14 to 19, where the ceramic gas delivery tube is placed in the central through opening and attached to an inside wall of the pedestal shaft structure.

Example 21. The method of one of examples 14 to 20, where attaching the ceramic pedestal shaft includes performing a diffusion bonding process.

Example 22. The method of one of examples 14 to 21, where forming the pedestal shaft structure includes forming with a ceramic material selected from a group consisting of aluminum nitride, aluminum oxide, silicon nitride, silicon carbide, and boron nitride.

Example 23. The method of one of examples 14 to 22, where an inside diameter of the ceramic gas delivery tube is between 1 mm and 10 mm.

Example 24. A method of forming a wafer pedestal assembly that includes: forming a pedestal shaft structure including a central through opening and a metal tube within a wall of the pedestal shaft structure; sintering the pedestal shaft structure to form a pedestal shaft with the metal tube; etching the metal tube to form a gas delivery tube disposed within the wall of the pedestal shaft; and attaching the pedestal shaft to a ceramic wafer chuck with the ceramic gas delivery tube being aligned to a gas channel opening of the ceramic wafer chuck.

Example 25. The method of example 24, where forming the pedestal shaft structure includes performing a compression molding process.

Example 26. The method of one of examples 24 or 25, where forming the pedestal shaft structure includes performing an injection molding process.

Example 27. The method of one of examples 24 to 26, where forming the pedestal shaft structure includes performing a 3-D printing process.

Example 28. The method of one of examples 24 to 27, where forming the pedestal shaft structure includes forming the pedestal shaft structure from a ceramic material selected from a group consisting of aluminum nitride, aluminum oxide, silicon nitride, silicon carbide, and boron nitride.

Example 29. The method of one of examples 24 to 28, where an outside diameter of the metal tube is between 1 mm and 10 mm.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor processing apparatus comprising:
a wafer pedestal comprising a ceramic pedestal shaft coupled to an underside of a ceramic wafer chuck, the ceramic pedestal shaft having a central through opening; and
ceramic gas delivery tubes embedded within the ceramic pedestal shaft, the ceramic gas delivery tubes being made of a first ceramic material and the ceramic pedestal shaft being made of a second ceramic material, the ceramic gas delivery tubes being coupled to gas channels in the ceramic wafer chuck.

2. The apparatus of claim 1, wherein the first ceramic material and the second ceramic material are separated from each other by an interface region.

3. The apparatus of claim 1, wherein the first ceramic material and the second ceramic material have different chemical composition.

4. The apparatus of claim 1, further comprising:
a first of the ceramic gas delivery tubes centered within the through opening and coupled to a first gas channel opening in a center of the underside of the ceramic wafer chuck; and
a second of the ceramic gas delivery tubes embedded in a wall of the ceramic pedestal shaft and coupled to a second gas channel opening in a peripheral region of the underside of the ceramic wafer chuck.

5. The apparatus of claim 1, further comprising:
a first of the ceramic gas delivery tubes centered within the through opening and coupled to a gas channel opening in a center of the underside of the ceramic wafer chuck; and
a second of the ceramic gas delivery tubes disposed within the central through opening and attached to an inside wall of the ceramic pedestal shaft.

6. The apparatus of claim 1, further comprising a resistance heater embedded in one of the ceramic gas delivery tubes.

7. The apparatus of claim 1, further comprising a cooling tube coiled around one of the ceramic gas delivery tubes.

8. The apparatus of claim 7, wherein the cooling tube comprises a metal selected from a group consisting of nickel, tungsten, molybdenum, titanium, and tungsten carbide.

9. The apparatus of claim 1, further comprising a resistance heater embedded in one of the ceramic gas delivery tubes and with a cooling tube coiled around one of the ceramic gas delivery tubes with an embedded resistance heater.

10. The apparatus of claim 1, wherein the ceramic pedestal shaft is made of a ceramic material selected from a group consisting of aluminum nitride, aluminum oxide, silicon nitride, silicon carbide, and boron nitride.

11. The apparatus of claim 1, wherein the first ceramic material is selected from a group consisting of aluminum nitride, aluminum oxide, silicon nitride, silicon carbide, and boron nitride.

12. The apparatus of claim 1, wherein the first ceramic material and the second ceramic material are made of aluminum nitride.

13. The apparatus of claim 1, wherein the ceramic pedestal shaft is diffusion bonded to the underside of the ceramic wafer chuck.

14. A method of forming a wafer pedestal assembly, the method comprising:
forming a pedestal shaft structure comprising an central through opening and a ceramic gas delivery tube;
sintering the pedestal shaft structure to form a ceramic pedestal shaft with the ceramic gas delivery tube;
aligning the ceramic gas delivery tube with a gas channel opening of a ceramic wafer chuck; and
attaching the ceramic pedestal shaft to the ceramic wafer chuck with the ceramic gas delivery tube being aligned to the gas channel opening.

15. The method of claim 14, wherein forming the pedestal shaft structure comprises
placing the ceramic gas delivery tube in a mold,
performing a powder coating process to coat the ceramic gas delivery tube with a ceramic powder, and
removing the pedestal shaft structure from the mold after a curing process.

16. The method of claim 14, wherein forming the pedestal shaft structure comprises performing a compression molding process.

17. The method of claim 14, wherein forming the pedestal shaft structure comprises performing an injection molding process.

18. The method of claim 14, wherein forming the pedestal shaft structure comprises performing a 3-D printing process.

19. The method of claim 14, wherein the ceramic gas delivery tube is placed within a wall of the pedestal shaft structure.

20. The method of claim 14, wherein the ceramic gas delivery tube is placed in the central through opening and attached to an inside wall of the pedestal shaft structure.

21. The method of claim 14, wherein attaching the ceramic pedestal shaft comprises performing a diffusion bonding process.

22. The method of claim 14, wherein forming the pedestal shaft structure comprises forming with a ceramic material selected from a group consisting of aluminum nitride, aluminum oxide, silicon nitride, silicon carbide, and boron nitride.

23. The method of claim 14, wherein an inside diameter of the ceramic gas delivery tube is between 1 mm and 10 mm.

24. A method of forming a wafer pedestal assembly, the method comprising:
forming a pedestal shaft structure comprising a central through opening and a metal tube within a wall of the pedestal shaft structure;
sintering the pedestal shaft structure to form a pedestal shaft with the metal tube;
etching the metal tube to form a gas delivery tube disposed within the wall of the pedestal shaft; and
attaching the pedestal shaft to a ceramic wafer chuck with the gas delivery tube being aligned to a gas channel opening of the ceramic wafer chuck.

25. The method of claim 24, wherein forming the pedestal shaft structure comprises performing a compression molding process.

26. The method of claim 24, wherein forming the pedestal shaft structure comprises performing an injection molding process.

27. The method of claim 24, wherein forming the pedestal shaft structure comprises performing a 3-D printing process.

28. The method of claim 24, wherein forming the pedestal shaft structure comprises forming the pedestal shaft structure from a ceramic material selected from a group consisting of aluminum nitride, aluminum oxide, silicon nitride, silicon carbide, and boron nitride.

29. The method of claim 24, wherein an outside diameter of the metal tube is between 1 mm and 10 mm.
